(19) United States
(12) Patent Application Publication
(10) Pub. No.: US 2006/0279000 A1
(43) Pub. Date: Dec. 14, 2006

(54) Pre-solder structure on semiconductor package substrate and method for fabricating the same

(76) Inventors: Ruei-Chih Chang, Hsin-chu (TW); Chu-Chin Hu, Hsin-chu (TW)

Correspondence Address: CLARK & BRODY, 1090 VERMONT AVENUE, NW, SUITE 250, WASHINGTON, DC, 20005, US

(21) Appl. No.: 11/407,185

(22) Filed: Apr. 20, 2006

Related U.S. Application Data
(63) Continuation-in-part of application No. 10/876,474, filed on Jun. 28, 2004, now abandoned.

(30) Foreign Application Priority Data
Jan. 30, 2004 (TW) 093102095

(51) Int. Cl. H01L 21/44; H01L 21/4763; H01L 23/48

(52) U.S. Cl. 257/779; 438/612; 438/613; 438/614; 438/637; 257/E23.02

(57) ABSTRACT

A pre-solder structure on a semiconductor package substrate and a method for fabricating the same are proposed. A plurality of conductive pads are formed on the substrate, and a protective layer having a plurality of openings for exposing the conductive pads is formed over the substrate. A conductive seed layer is deposited over the protective layer and openings. A patterned resist layer is formed on the seed layer and has openings corresponding in position to the conductive pads. A plurality of conductive pillars and a solder material are deposited in sequence in each of the openings. The resist layer and the seed layer not covered by the conductive pillars and the solder material are removed. The solder material is subject to a reflow-soldering process to form pre-solder bumps covering the conductive pillars.

### FIELD OF THE INVENTION

The present invention relates to pre-solder structures on semiconductor package substrates and methods for fabricating the same, and more particularly, to a method for fabricating the pre-solder structure on conductive pads of the substrate by electroplating and etching techniques.

### BACKGROUND OF THE INVENTION

It has been an endeavor to develop a compact semiconductor package with fine-pitch arrangement of circuits and pads. Packages having miniaturized integrated circuits (IC) and dense contacts or leads, such as BGA (ball grid array) package, flip-chip package, chip scale package (CSP) and multi-chip module (MCM), become the mainstream on the market. In the flip-chip package, a plurality of electrode pads are formed on a surface of the IC chip, and corresponding conductive pads are formed on a circuit board, such that solder bumps or other conductive adhesive material can be used to interconnect the electrode pads of the chip and the conductive pads of the circuit board, making the chip attached to the circuit board in a face-down manner.

The pre-solder structure formed by the solder bumps or conductive adhesive material provides the input/output (I/O) connection and the mechanical connection between the chip and the circuit board. Such a conventional pre-solder structure in the flip-chip package is shown in FIGS. 1, 2 and 3 respectively.

As shown in FIG. 1, a plurality of metal bumps 11 are formed on the electrode pads 12 of a chip 13, and a plurality of pre-solder bumps 14 made of solder material are formed on the conductive pads 15 of the circuit board 16. At a temperature sufficient to melt the pre-solder bumps 14, the pre-solder bumps 14 are reflow-soldered to form solder joints 17 on the metal bumps 11. An underfill material 18 may be used to fill the gap between the chip 13 and the circuit board 16, which provides a buffer effect to diminish the mismatch of thermal expansion between the chip 13 and the circuit board 16 and also reduce the stress of the solder joints 17.

As shown in FIG. 2, in another case, a plurality of contact pads 21a and conductive traces 21b are formed on a surface of a circuit board 2. The contact pads 21a and conductive traces 21b are made of metal, such as copper. AD organic protective layer 24 such as a solder mask layer made of epoxy design is formed on the surface of the circuit board 2, and has a plurality of openings to expose the contact pads 21a on the circuit board 2. Lastly, pre-solder bumps 25 are formed on the contact pads 21a to subsequently form flip-chip solder joints.

As shown in FIG. 3, a package substrate 30 is formed on a surface thereof with a plurality of conductive pads 32 where a solder material (not shown) such as solder paste is subsequently to be deposited. A solder mask layer 31 such as green paint is applied over the surface of the substrate 30, with the conductive pads 32 exposed from the solder mask layer 31. A stencil 33 having a plurality of grid openings 33a is disposed on the substrate 30. The solder material is applied on the stencil 33, using a roller 34 or a spraying method to spread the solder material into the grid openings 33a of the stencil 33, such that the solder material is deposited on the conductive pads 32 after the stencil 33 is removed. Next, a reflow-soldering process is performed at a temperature sufficient to melt the solder material so as to form solder bumps (not shown) on the conductive pads 32 of the substrate 30. As a result, the pre-solder structure is fabricated on the package substrate via the stencil printing technique. The related prior arts include U.S. Pat. Nos. 5,672,542, 6,047,637 and 6,551,917, to name just a few, which disclose the stencil printing technology and the fabrication of pre-solder bumps using the stencil printing technology. To achieve profile miniaturization and increased functionality, circuits formed on the circuit board or package substrate are getting more densely arranged, and a pad pitch between adjacent contact/conductive pads on the circuit board or substrate is also becoming smaller. Under this condition, the area of the contact/conductive pads exposed from the solder mask layer is also reduced making the solder bumps difficult to align with and well bonded to the exposed area of the pads. This would adversely affect the yield of the stencil printing technology and cause flash of the solder material melted during the reflow-soldering process.

Moreover, as the solder material is viscose, the more frequent performances of stencil printing leave more the solder material remaining on the inner walls of the stencil openings, which would make the amount and shape of the solder material in subsequent printing procedures not match the predetermined design. Further, the stencil openings should be sized in accordance with the dimension of the solder mask layer, leading to an increase in the cost for fabricating the stencil. Another difficulty may occur when a pitch between adjacent stencil openings is too small to allow the solder material to flow into the stencil openings.

Therefore, the above conventional pre-solder structure formed on the substrate suffers significant problems such as increased material cost, difficulties during the fabrication processes and degraded reliability. Since the pitch between the conductive pads cannot be reduced, migration of copper particles and flash of the melted solder materials during reflow-soldering are caused thus leading to bridging or short circuit between two conductive pads.

U.S. Pat. No. 5,926,731 discloses formation of a non-solder material layer on the package substrate, with pillars made of solder material formed on the non-solder material layer. Solder bumps made of solder material are received on upper surfaces of the solder pillars. After the reflow-soldering process, the solder pillars define the shape and height of the solder bumps. However, a large amount of the solder material is required to ensure solder joints of the solder bump. The solder material has high cost and requires longer time to be formed by electroplating as well as is not easy to be defined in location, thereby prolonging the fabrication time and increasing the fabrication complexity and cost.

Further, a resist layer with a plurality of openings formed on the surface of package substrate to define the positions where the solder material is deposited. However, the longer time required for electroplating the large amount of the solder material causes the solder material easy to permeate the electroplated resist layer. And formation of the resist layer involves complex processes, thereby undesirably increasing the fabrication complexity.

Therefore, it is greatly desired to provide a method for fabricating a pre-solder structure on a substrate, which can resolve the above problems so as to increase the yield, reduce the material cost, prevent the occurrence of bridge or short circuit effect, and ensure the reliability.

### SUMMARY OF THE INVENTION

In light of the prior-art drawbacks, an objective of the present invention is to provide a pre-solder structure on a semiconductor package substrate and a method for fabricating the same, which can reduce the amount of a solder material used.

Another objective of the present invention is to provide a pre-solder structure on a semiconductor package substrate and a method for fabricating the same, which can prevent permeation of the solder material.

Still another objective of the present invention is to provide a pre-solder structure on a semiconductor package substrate and a method for fabricating the same, which can prevent bridging from occurrence and allow a pad pitch between adjacent conductive pads on the substrate to be reduced.

A further objective of the present invention is to provide a pre-solder structure on a semiconductor package substrate and a method for fabricating the same so as to reduce the material cost.

A further objective of the present invention is to provide a pre-solder structure on a semiconductor package substrate and a method for fabricating the same so as to shorten the fabrication lime.

In accordance with the above and other objectives, the present invention proposes a method for fabricating a pre-solder structure on a semiconductor package substrate, including the steps of: providing the semiconductor package substrate having a plurality of conductive pads formed on at least one surface thereof; forming a protective layer on the surface of the substrate, wherein the protective layer has a plurality of openings to expose the conductive pads; forming a conductive seed layer over the protective layer and the exposed conductive pads, and forming a resist layer on the seed layer, wherein the resist layer is patterned to form a plurality of openings corresponding in position to the conductive pads; and electroplating a conductive pillar and a solder material in sequence in each of the openings.

The pre-solder structure formed on the semiconductor package substrate by the above fabrication method includes a plurality of conductive pads, a conductive seed layer, a plurality of conductive pillars, and a solder material. The conductive pads are formed on the surface of the substrate. A protective layer is formed over the surface of the substrate and has a plurality of openings to expose the conductive pads. The seed layer is formed over the protective layer and the exposed conductive pads. The conductive pillars are formed on the seed layer corresponding in position to the conductive pads. The solder material is deposited on the conductive pillars and subject to a reflow-soldering process to form pre-solder bumps that cover the top and side portions of the conductive pillars.

A characteristic feature of the above fabrication method is to firstly form the seed layer and conductive pillars on the surface of the substrate, and then deposit a solder material by electroplating on the conductive pillars. This is advantageous in that the conductive pillars preferably made of low-cost copper can be formed by electroplating at a higher speed, and then the high-cost solder material is electroplated at lower speed, thereby only using a small amount of the solder material.

A pad pitch is customarily defined as a distance between centers of two adjacent conductive pads, and a pad distance is customarily defined as the smallest distance between circumferences of two adjacent conductive pads.

Moreover, the conductive pillars are subject to the side-etching effect that a side portion of the conductive pillar is etched away during a process to remove the seed layer by etching, such that the pad distance between the conductive pillars would be increased which can prevent migration of copper ions between the conductive pillars, and the pad pitch between the conductive pads can thus be reduced. Further, the fabrication method in the present invention can avoid the prior-art problem of a need to adjust the size of stencil openings according to the change of the size and pad pitch of conductive pads thereby leading to an increase in the fabrication cost, and the prior-art drawbacks of concerning the frequency of stencil printing and cleaning of the stencil.

Therefore, the pre-solder structure fabricated on the substrate according to the present invention desirably eliminates the prior-art drawbacks to prevent infiltration and bridging of the solder material, and also requires a reduced amount of the solder material which can shorten the fabrication time, as well as the pad pitch between the conductive pads on the semiconductor package substrate can be reduced.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional flip-chip device;

FIG. 2 (PRIOR ART) is a cross-sectional view of a conventional circuit board having a protective layer and pre-solder bumps formed thereon;

FIG. 3 (PRIOR ART) is a cross-sectional view showing deposition of a solder material on conductive pads of a semiconductor package substrate by a stencil printing technique; and

FIGS. 4A to 4I are cross-sectional views showing procedural steps of a method for fabricating a pre-solder structure on a semiconductor package substrate according to the present invention.

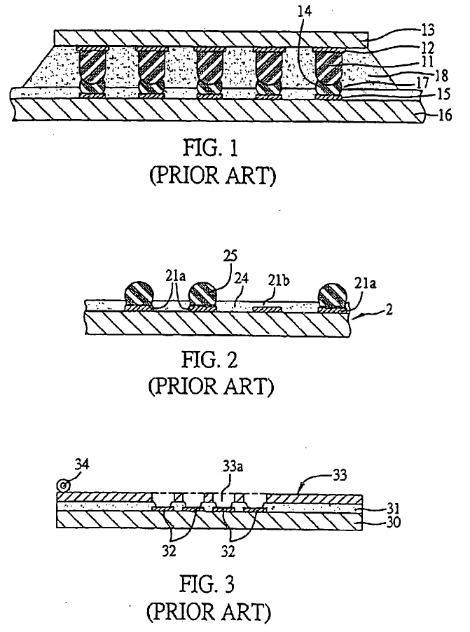

### DETAILED DESCRIPTION OF THE PREFERRED EMBODIMENTS

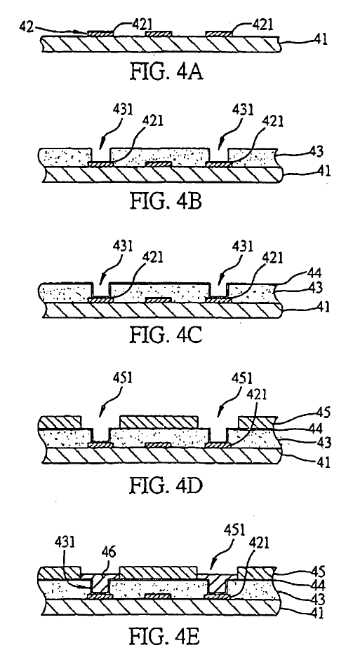

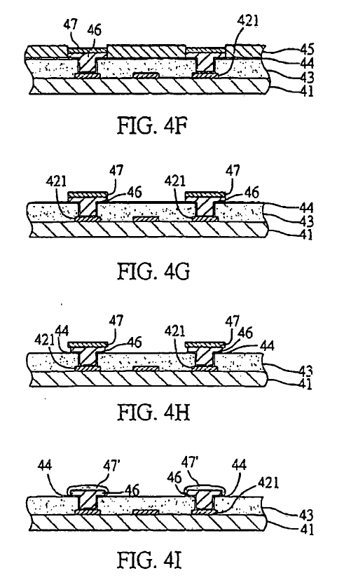

The preferred embodiments of a pre-solder structure on a semiconductor package substrate and a method for fabricating the same proposed in the present invention are described in detail with reference to FIGS. 4A to 4K.

Referring to FIG. 4A, a semiconductor package substrate 41 is provided. The substrate 41 is subject in advance to an early stage of circuit patterning to form a conductive circuit layer 42 having a plurality of conductive pads 421 on at least one surface of the substrate 41. Fabrication of the conductive circuit layer 42 and conductive pads 421 on the substrate 41 employs conventional techniques, thus not to be further detailed herein.

Referring to FIG. 4B, a protective layer 43 such as solder mask or green paint made of epoxy resign is coated on the surface of the substrate 41 having the conductive pads 421. In this embodiment, the protective layer 43 can be formed by the printing, spin-coating or attaching technique. The protective layer 43 is patterned to form a plurality of openings 431 via which the conductive pads 421 are exposed.

Referring to FIG. 4C, a conductive seed layer 44 is formed over the protective layer 43 and the exposed conductive pads 421. The seed layer 44 serves as a conductive layer for a subsequent electroplating process. The seed layer 44 can be made of a metal, an alloy, or several deposited metal layers, such as Copper (Cu), Tin (Sn), Nickel (Ni), Chromium (Cr), Titanium (Ti), Cu/Cr alloy or Sn/Lead (Pb) alloy. The seed layer 44 may be formed by the physical vapor deposition (PVD), chemical vapor deposition (CVD), electroless plating or chemical deposition technique, such as sputtering, evaporation, arc vapor deposition, ion beam sputtering, laser ablation deposition, or plasma enhanced chemical vapor deposition (PECVD). Preferably the seed layer 44 is made by the electroless-plated copper.

Referring to FIG. 4D, a resist layer 45 is formed on the seed layer 44. The resist layer 45 can be made of a dry-film photoresist or liquid photoresist by the printing, spin-coating, or attaching technique. Then, the resist 45 is patterned by exposing and developing techniques to form a plurality of openings 451 corresponding in position to the conductive pads 421, such that the resist layer 45 covers only the part of the seed layer 44 lying on the protective layer 43.

Referring to FIG. 4E, the substrate 41 is subject to an electroplating process. The seed layer 44 serves as a conductive layer to allow a conductive pillar 46 to be formed by electroplating in each of the openings 451. The conductive pillars 46 can be made of a metal selected from the group consisting of Pb, Sn, Silver (Ag), Cu, Gold (Au), Bismuth (Bi), Antimony (Sb), Zinc (Zn), Ni, Zirconium (Zr), Magnesium (Mg), Indium (In), Tellurium (Te), and Gallium (Ga).

Cu is well used and has relatively lower cost, such that the conductive pillars 46 are preferably made by the electroplated Cu. In this embodiment, the top of the conductive pillars 46 may be protruded from the openings 431 of the protective layer 43.

Referring to FIG. 4F, an electroplating process is performed on the conductive pillars 46. Since the conductive pillars 46 have conductivity and the seed layer 44 serves as the conductive layer, a solder material 47 can be electroplated on each of the conductive pillars 46. The solder material 47 may be an alloy made of metals selected from the group consisting of Pb, Sn, Ag, Cu, Au, Bi, Sb, Zn, Ni, Zr, Mg, In, Te and Ga.

Referring to FIG. 4G, the resist layer 45 of FIG. 4F can be removed by the conventional stripping technique that is not to be detailed herein.

Referring to FIG. 4H a part of the seed layer 44 not covered by the conductive pillars 46 and the solder material 47 is removed by a conventional technique such as etching. During etching, the etchant for removing the seed layer 44 may also react on the conductive pillars 46 and etch away a side portion of the conductive pillar 46, which is called “side-etching effect”. As a result, the etched side portion of the conductive is pillar 46 forms a stepped structure together with the solder material 47, and the conductive pillar 46 is protruded out of the protective layer 43 for exposing the side portion thereof.

The seed layer 44 may be a very thin film to shorten the time required for removal of the seed layer 44 by etching. Alternatively, a relatively thicker seed layer 44 can be used to accelerate current flow therethrough so as to shorten the time required for electroplating and achieve better electroplating results. It would not damage the circuits on the substrate 41 when removing the thicker seed layer 44. The thicker seed layer 44 and the conductive pillars 46 having a predetermined height not only facilitate the current flow but also reduce the required amount of the solder material 47. The copper-made conductive pillars 46 provide preferable reliability, which can achieve better electroplating results and prevent the prior-art problem of infiltration of the solder material.

As shown in FIG. 4H, the pre-solder structure formed on the substrate 41 by the fabrication method according to the present invention comprises the plurality of conductive pads 421, the seed layer 44, the conductive pillars 46, and the solder material 47. The conductive pads 421 are formed on the surface of the substrate 41 and exposed from the protective layer 43. The seed layer 44 completely covers the exposed conductive pads 421, allowing the conductive pillars 46 to be formed by electroplating on the seed layer 44 lying over the conductive pads 421. The solder material 47 is deposited on the conductive pillars 46. The seed layer 44 and the conductive pillars 46 may be preferably made of, but not limited to, Cu.

Referring to FIG. 4I, a reflow-soldering process can be performed under a temperature sufficient to melt the solder material 47, making the solder material 47 reflow-soldered 10 form pre-solder bumps 47′ on the top and side portions of the conductive pillars 46. The pre-solder bumps 47′ are electrically connected to the conductive pads 421 via the conductive pillars 46, and the pre-solder bumps 47 cover the top and side portions of the conductive pillars 46.

According to the method for fabricating the pre-solder structure on the semiconductor pack-age substrate in the present invention, two electroplating processes are performed to form the conductive pillars and the solder material in sequence on the conductive pads of the substrate. In particular, the conductive pillars made of low-cost materials are firstly plated on the conductive pads; then, the conductive pillars and the conductive seed layer thereon serve as the conductive layer to allow a relatively smaller amount of the high-cost solder material to be deposited on the conductive pillars. After the resist layer and the seed layer not covered by the electroplated conductive pillars and the solder material are removed, the solder material is subject to the reflow-soldering process to form the pre-solder bumps completely covering the conductive pillars.

Therefore, it is advantageous to use the low-cost conductive pillars to replace part of the solder material, such that the amount of the solder material used and the material cost can both be reduced, and also the prior-art problem of damage to the circuits on the substrate can be eliminated. Moreover, the fabrication method in the present invention can avoid the prior-art problem of a need to adjust the size of stencil openings according to the change of the size and pad pitch of conductive pads thereby leading to an increase in the fabrication cost, and the prior-art drawbacks of concerning the usage frequency of stencil printing and cleaning of the stencil.

Since the conductive pillars 46 are subject to the side-etching effect during the etching process to remove the seed layer 44, the pad distance between the conductive pillars 46 would be increased which can prevent migration of copper ions between the conductive pillars 46, such that the pad pitch between the conductive pads 421 can be reduced making the pre-solder structure suitably formed on the fine pad-pitch substrate by the fabrication method according to the present invention. Moreover, since the time required for electroplating the copper pillars 46 is shorter than that for electroplating the solder material 47, such that the fabrication method according to the present invention is also advantageous of shortening the fabrication time and accelerating the fabrication progress.

In addition, another advantage of the fabrication method according to the present invention in which the conductive pillars and the solder material are formed in sequence on the conductive pads is that the prior-art permeate of the solder material into the electroplated resist layer can be prevented, and the prior-art bridging problem in the reflow-soldering process can be avoided.

It should be understood that the number and distribution of the conductive pads and the pre-solder bumps can be flexibly arranged on the substrate depending on the practical requirements. The fabrication method according to the present invention may be implemented on a single side or double sides of the substrate. Also, a circuit board with fine circuitry requiring pre-solder bumps is suitably used in the present invention.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A pre-solder structure on a semiconductor package substrate, comprising:
at least one conductive pad formed on at least one surface of the semiconductor package substrate;
a protective layer formed on the surface of the substrate and having a plurality of openings to expose the at least one conductive pad;
a conductive seed layer disposed on each of the at least one conductive pads;
a conductive pillar formed on the conductive seed layer on each of the at least one conductive pads, wherein the conductive pillar is protruded from the opening of the protective layer for exposing the side portion thereof; and
a solder material deposited to cover the top and side portions of the conductive pillar, wherein an outward stepped structure is formed by the conductive pillar and the solder material.

2. A method for fabricating a pre-solder structure on a semiconductor package substrate, comprising the steps of:
providing the semiconductor package substrate having a plurality of conductive pads formed on at least one surface thereof;
forming a protective layer on the surface of the substrate, wherein the protective layer has a plurality of openings to expose the conductive pads;
forming a conductive seed layer over the protective layer and the exposed plurality of conductive pads, and forming a resist layer on the seed layer, wherein the resist layer is patterned to form a plurality of opening corresponding in position to the plurality of conductive pads;
forming a conductive pillar and a solder material in sequence in each of the openings by an electroplating process;
Removing the resist layer and a part of the seed layer not covered by the conductive pillars and the solder material, wherein the conductive pillars and the solder material is protruded from the opening of the protective layer for exposing side portion thereof and further form a stepped structure;
Performing a reflow-soldering process for the solder material to form pre-older bumps on the conductive pillars, wherein the pre-solder bumps cover the top and side portions of the conductive pillars.

3. The method of claim 2, wherein the protective layer is coated on the surface of the substrate by printing, spin-coating or attaching, and a patterning process is performed to form the openings of the protective layer.

4. The method of claim 2, wherein the seed layer serves as a conductive path for forming the conductive pillar and the solder material.

5. The method of claim 2, wherein the resist layer is formed on the seed layer by printing, spin-coating or attaching, and is patterned by exposing and developing.

6. The method of claim 2, wherein the conductive pillar is made of a metal selected from the group consisting of Lead (Pb), Tin (Sn), Silver (Ag), Copper (Cu), Gold (Au), Bismuth (Bi), Antimony (Sb), Zinc (Zn), Nickel (Ni), Zirconium (Zr), Magnesium (Mg), Indium (In), Tellurium (Te), and Gallium (Ga).

7. The method of claim 2, wherein the seed layer is made of a material selected from the group consisting of Cu, Sn, Ni, Cr, Ti, Cu/Cr alloy, and Sn/Pb alloy.

8. The method of claim 2, wherein the solder material is an alloy made of metals selected from the group consisting of Pb, Sn, Ag, Cu, Au, Bi, Sb, Zn, Ni, Zr, Mg, In, Te, and Ga.
